(19) United States
(12) Patent Application Publication
(10) Pub. No.: US 2007/0164449 A1
(43) Pub. Date: Jul. 19, 2007

(54) BUILD-UP PACKAGE OF OPTOELECTRONIC CHIP

(75) Inventor: Chien-Hao Wang, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ADVANCED SEMICONDUCTOR ENGINEERING, INC., Kaohsiung (TW)

(21) Appl. No.: 11/615,996

(22) Filed: Dec. 25, 2006

(30) Foreign Application Priority Data
Dec. 30, 2005 (TW) 94147754

(51) Int. Cl. H01L 23/48

(52) U.S. Cl. 257/778

(57) ABSTRACT

A build-up package of an optoelectronic chip mainly includes a transparent circuit carrier board, at least one optoelectronic chip, at least one dielectric layer and at least one wiring layer of a build-up package. The optoelectronic chip is flip-chip bonded to the transparent circuit carrier board. The build-up package is formed on the transparent circuit carrier board, wherein the dielectric layer covers the optoelectronic chip and has a plurality of through holes, the wiring layer is formed on the dielectric layer and is electrically connected to a substrate wiring layer of the transparent circuit carrier board via the through holes. Accordingly, the build-up package of the optoelectronic chip is a thin optoelectronic product and improves the thermal dissipation, the encapsulation, and the compact of the electrical connection of the embedded optoelectronic chip.

### CROSS-REFERENCE TO RELATED APPLICATION

This application claims the priority benefit of Taiwan application serial no. 94147754, filed on Dec. 30, 2005. All disclosure of the Taiwan application is incorporated herein by reference.

### BACKGROUND OF THE INVENTION

1. Field of Invention

The present invention relates to a packaging technology of an optoelectronic chip. More particularly, the present invention relates to a build-up package and a method of an optoelectronic chip.

2. Description of Related Art

Optoelectronic chips have been applied to video electronic products, so as to provide various functions such as image sensing, image displaying, illuminating, optical storage, optical output or optical input. As the optoelectronic chips usually have a large package size, the assembly space for the video electronic products is occupied, and the electrical transmission path is quite long, thus a cross-talk effect easily occurs.

Referring to FIG. 1, an optoelectronic chip package 100 of an image sensor mainly includes a substrate 110, an optoelectronic chip 120, a plurality of bonding wires 130 and a transparent plate 140. The substrate 110 has an upper surface 111, a lower surface 112, and a wiring structure (not shown) electrically conducting the upper surface 111 and the lower surface 112. The substrate 110 usually is a multi-layer printed circuit board. An annular wall 113 is formed with the upper surface 111 of the substrate 110, so as to make the substrate 110 and the annular wall 113 form a chip-accommodating cavity 114. The optoelectronic chip 120 is an image sensing chip, and is disposed on the upper surface 111 of the substrate 110 by means of adhering and is located in the chip accommodating cavity 114. A sensing region 121 and a plurality of bonding pads 122 are formed on the active surface of the optoelectronic chip 120. The bonding wires 130 are formed in the chip accommodating cavity 114 by means of wiring process, and electrically connect the bonding pads 122 of the optoelectronic chip 120 and the substrate 110. The transparent plate 140 is disposed on the annular wall 113, so as to seal the optoelectronic chip 120 and the bonding wires 130. In the above optoelectronic chip package 100, the optoelectronic chip 120 is electrically conducted to a digital signal processor chip (not shown) on an external circuit board via the bonding wires 130 and the substrate 110, and the transmission path is relatively long, so that the image cannot be quickly processed and thus the cross-talk effect easily occurs.

Taiwan patent No. M246808 entitled “Build-up Structure for Image Sensor” has disclosed an image sensor package including a wiring build-up structure. An image sensing chip is accommodated in a chip cavity of a substrate and the image sensing chip has a sensing region facing upward. The wiring build-up structure is formed on the image sensing chip of the substrate. As the wiring build-up structure is formed on the active surface of the image sensing chip, and the wiring build-up structure must have a window which cannot shield the sensing region, the conductive wiring arranged in the wiring build-up structure is limited and cannot become compact. Moreover, it is required to reserve a window in the wiring build-up structure, such that the manufacturing cost is increased.

### SUMMARY OF THE INVENTION

Accordingly, the present invention is directed to provide a build-up package and a method of an optoelectronic chip. An optoelectronic chip is bonded to a transparent circuit carrier board by flip-chip process. A dielectric layer and a wiring layer of a build-up package are formed on the transparent circuit carrier board, wherein the dielectric layer covers the optoelectronic chip, and the wiring layer is electrically connected to a substrate wiring layer of the transparent circuit carrier board. Therefore, the dielectric layer and the wiring layer have no impact on an optoelectronic working region of the optoelectronic chip, and the compact wiring layer is obtained. According to the present invention, the thin optoelectronic products can be obtained, and the electrical interconnection and the encapsulation of the embedded optoelectronic chip can be improved. Thus, the assembility, the interconnection reliability and the electrical performance are improved; the subsequent packaging density is increased and the cross-talk effect is reduced.

The present invention is also directed to provide a build-up package and a method of an optoelectronic chip, wherein a dielectric layer is formed on the transparent circuit carrier board and is thicker than the optoelectronic chip. The dielectric layer covers a back surface and a plurality of side surfaces of the optoelectronic chip, so that a wiring layer formed on the dielectric layer have a plurality of wirings extending to above the back surface of the optoelectronic chip, and thus the compact wiring is obtained.

The present invention is further directed to provide a build-up package and a method of an optoelectronic chip, wherein at least one IC chip is disposed on a wiring layer of the build-up package, so as to be electrically interconnected to the optoelectronic chip, thus the electrical transmission path is reduced to accelerate the optoelectronic working rate.

According to the present invention, a build-up package of an optoelectronic chip mainly comprises a transparent circuit carrier board, at least one optoelectronic chip, a dielectric layer, and a wiring layer. The transparent circuit carrier board has a substrate wiring layer. The optoelectronic chip is flip-chip bonded to the transparent circuit carrier board and is electrically connected to the substrate wiring layer. The dielectric layer is formed on the transparent circuit carrier board and covers the optoelectronic chip. The dielectric layer has a plurality of through holes penetrating to the substrate wiring layer of the transparent circuit carrier board. The wiring layer is formed on the dielectric layer, and is electrically connected to the substrate wiring layer via the through holes.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a schematic cross-sectional view of a conventional optoelectronic chip package of an image sensor.

FIG. 2 is a schematic cross-sectional view of a build-up package of an optoelectronic chip according to an embodiment of the present invention.

FIGS. 3A to 3H are schematic cross-sectional views of the build-up package of the optoelectronic chip during the manufacturing process according to the first embodiment of the present invention.

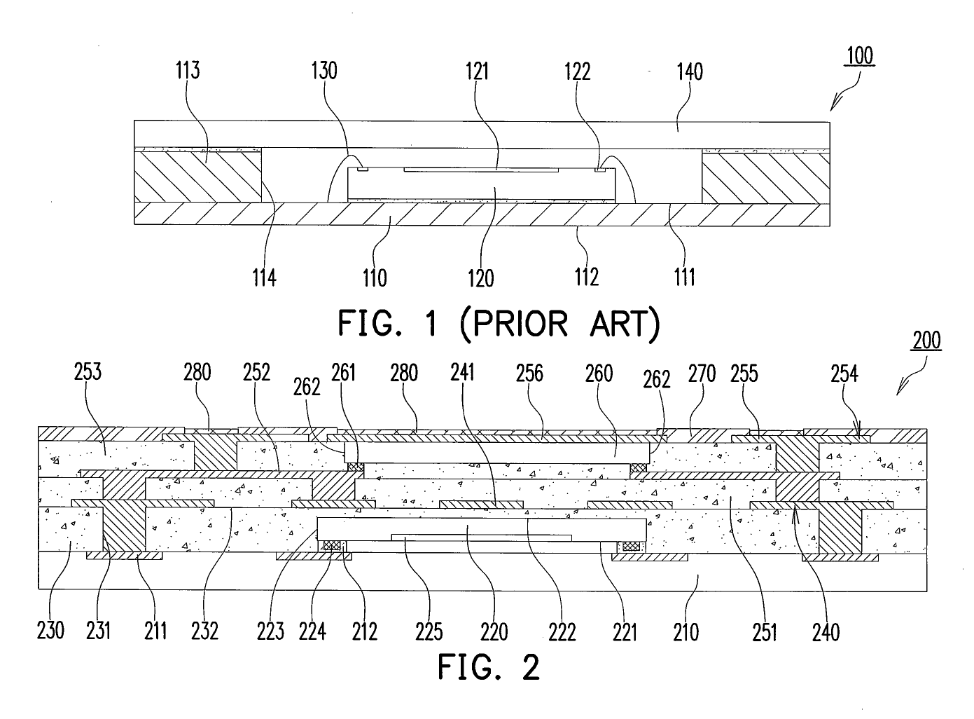

### DESCRIPTION OF EMBODIMENTS

Referring to FIG. 2, a build-up package 200 of an optoelectronic chip mainly includes a transparent circuit carrier board 210, at least one optoelectronic chip 220, a first dielectric layer 230, and a first wiring layer 240. The optoelectronic chip 220 is flip-chip bonded to the transparent circuit carrier board 210. The first dielectric layer 230 and the first wiring layer 240 are successively built up on the transparent circuit carrier board 210, wherein the first dielectric layer 230 covers the optoelectronic chip 220, and the first wiring layer 240 is formed on the first dielectric layer 230.

The transparent circuit carrier board 210 has a substrate wiring layer 211. The transparent circuit carrier board 210 usually is a glass substrate. The substrate wiring layer 211 is selected from an ITO (Indium Tin Oxide) conductive wiring layer or other metal wiring layers. Two ends of the plurality of wirings of the substrate wiring layer 211 are formed with a connecting finger electrically connected to the optoelectronic chip 220 and a connection pad (not shown) electrically connected to the first wiring layer 240.

The optoelectronic chip 220 has an active surface 221, an opposite back surface 222, and a plurality of side surfaces 223 between the active surface 221 and the back surface 222. The active surface 221 includes an optoelectronic working region 225. In this embodiment, the optoelectronic chip 220 is a CMOS (complementary metal oxide semiconductor) image sensing chip, and the optical sensing components such as pixels are disposed in the optoelectronic working region 225. Moreover, a plurality of bumps 224 are disposed on the active surface 221. The optoelectronic chip 220 is flip-chip bonded to the transparent circuit carrier board 210, and then is electrically connected to the substrate wiring layer 211 via the bumps 224. The flip-chip bonding method of the optoelectronic chip 220 can be one selected from among reflowing of solder or bumps, ultrasonic thermocompression bonding, antisotropic conducting, or nonconductive particle conducting.

The first dielectric layer 230 is formed on the transparent circuit carrier board 210, and the material of the first dielectric layer 230 can be an electrical insulating material such as polyimide (PI) or polyethylene terephthalate (PET). The first dielectric layer 230 has a plurality of through holes 231, and the through holes 231 penetrate to the external connection pad of the substrate wiring layer 211. Preferably, the first dielectric layer 230 is thicker than the optoelectronic chip 220, that is, the thickness of the first dielectric layer 230 from the upper surface of the transparent circuit carrier board 210 to an external surface 232 of the first dielectric layer 230 is larger than the thickness of the optoelectronic chip 220 from the active surface 221 to the back surface 222. Thus, the first dielectric layer 230 can cover the back surface 222 and the side surfaces 223 of the optoelectronic chip 220. The first wiring layer 240 is formed on the outer surface 232 of the first dielectric layer 230, and is electrically connected to the external connection pad of the substrate wiring layer 211 via the through holes 231 of the first dielectric layer 230. The first wiring layer 240 may have a plurality of wirings 241 extending to above the optoelectronic chip 220, so that the compact wiring is obtained and the number of the formed wiring layers required by a build-up package can be reduced.

Therefore, in the present invention, the dielectric layer and the wiring layer of a build-up package are inversely formed on the transparent circuit carrier board 210 which has the optoelectronic chip 220 already disposed, such that the optoelectronic working region 255 of the optoelectronic chip 220 in the active surface 221 will not be affected, and the wiring layer may be designed to be compact. Therefore, the thin optoelectronic products can be obtained and the electrical interconnection and the encapsulation of the embedded optoelectronic chip 220 can be improved. Therefore, the assembility, the interconnection reliability, and the electrical performance are improved; the subsequent packaging density is increased and the cross-talk effect is reduced. The present invention is particularly applicable to the multi-chip optoelectronic package.

Moreover, in order to meet the requirements of the wiring, the build-up package on the transparent circuit carrier board 210 further includes at least one second dielectric layer 251 and at least one second wiring layer 252. The second dielectric layer 251 is formed on the first wiring layer 240, and the second wiring layer 252 is formed on the second dielectric layer 251 and electrically connected to the first wiring layer 240. In this embodiment, the build-up package 200 of the optoelectronic chip is an integrated multi-chip optoelectronic packaging product, and further includes at least one IC chip 260, for example a digital signal processor (DSP) chip, disposed on the second wiring layer 252. A plurality of electrodes 261 of the IC chip 260 is electrically bonded to the second wiring layer 252 by means of flip-chip bonding. The IC chip 260 is electrically connected to the optoelectronic chip 220 via the first wiring layer 240 and the second wiring layer 252. Therefore, the image received by the optoelectronic chip 220 can be quickly processed under an extremely short electrical transmission path, and the cross-talk effect can be reduced.

In this embodiment, the build-up package may further include at least one third dielectric layer 253 formed on the second wiring layer 252. The third dielectric layer 253 covers a plurality of side surfaces 262 of the IC chip 260, such that the IC chip 260 can be embedded and further protected. Further, a third wiring layer 254 can be formed on the third dielectric layer 253, and has a plurality of external connection pads 255. Preferably, the third wiring layer 254 further includes a heat sink portion 256 adhered on an exposed surface of the IC chip 260, thereby enhancing the thermal dissipation and preventing the colliding of the IC chip 260, or a heat sink can be further adhered on an exposed surface (not shown) of the IC chip 260. Moreover, the build-up package 200 of the optoelectronic chip further includes a solder mask layer 270 formed on the third wiring layer 254 and the third dielectric layer 253 to cover and protect the wirings of the third wiring layer 254. The solder mask layer 270 exposes the connection pads 255 and the heat sink portion 256, so that the connection pads 255 and the heat sink portion 256 have an exposed surface. Preferably, an electroplated layer 280 (e.g. nickel-gold) can be formed on the exposed surface of the connection pads 255 and the heat sink portion 256, so as to prevent the oxidation of the connection pads 255 and the heat sink portion 256.

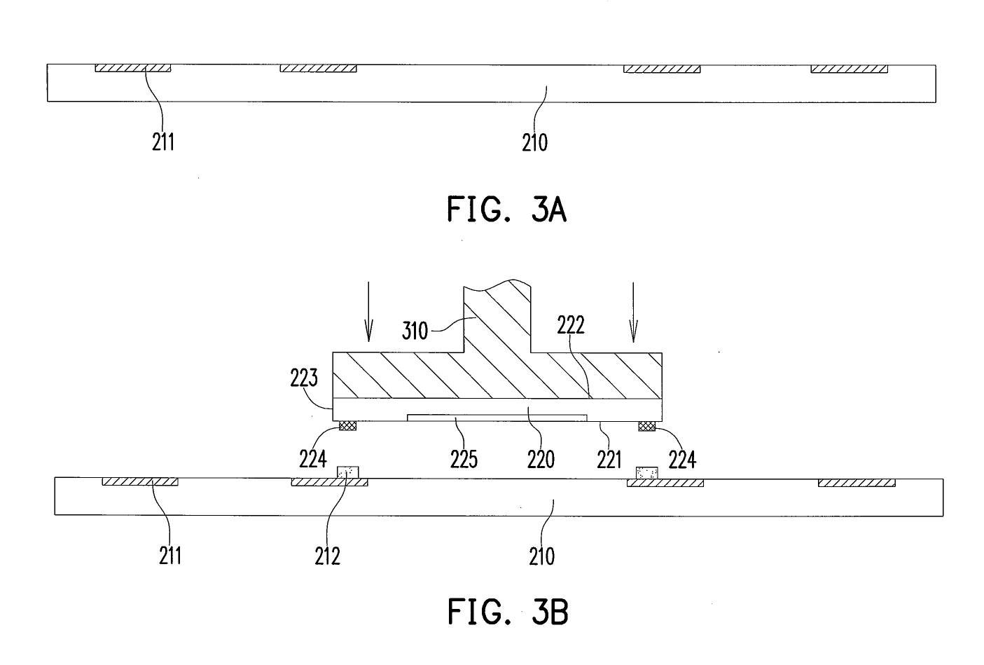

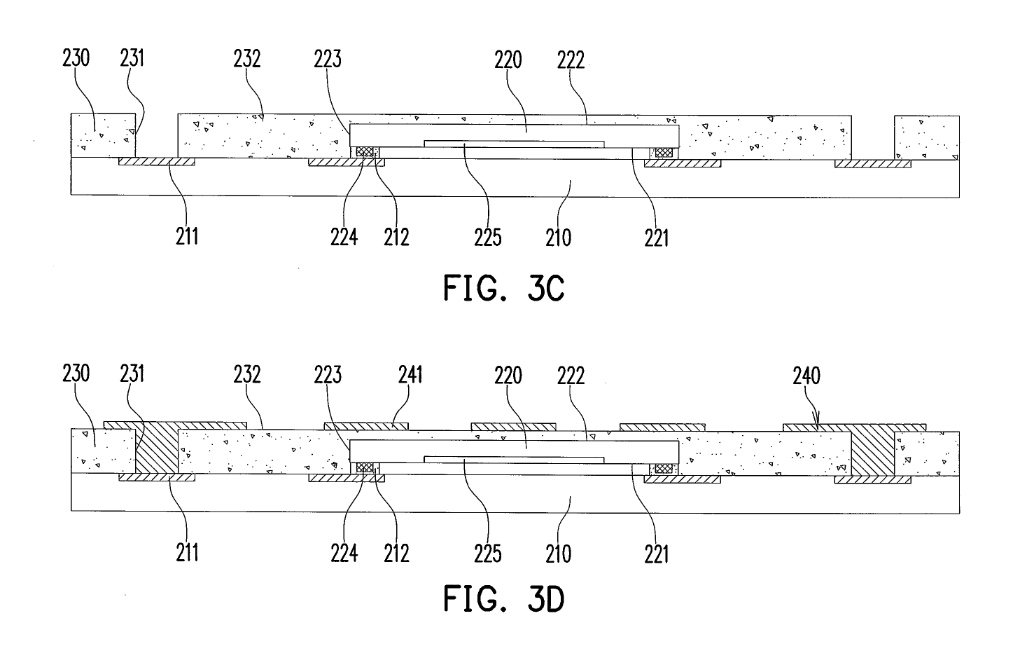

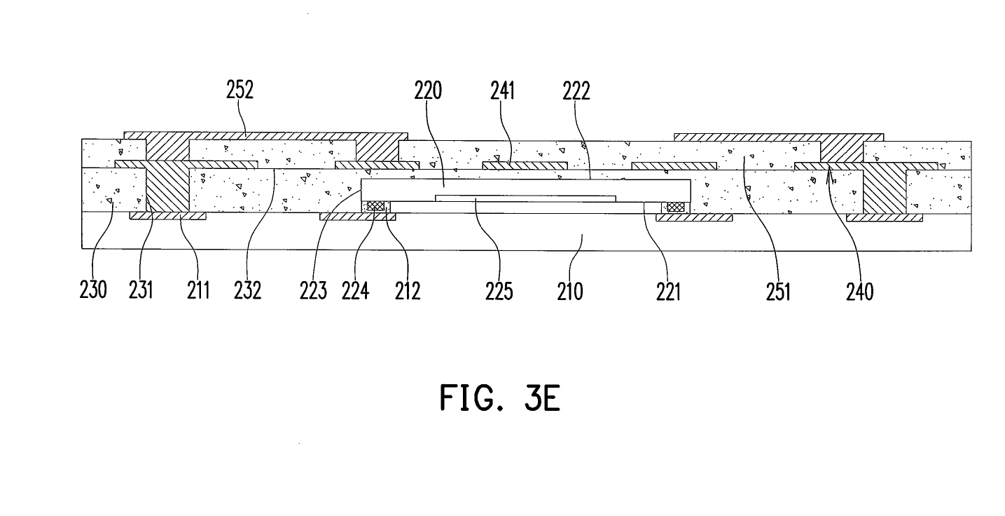

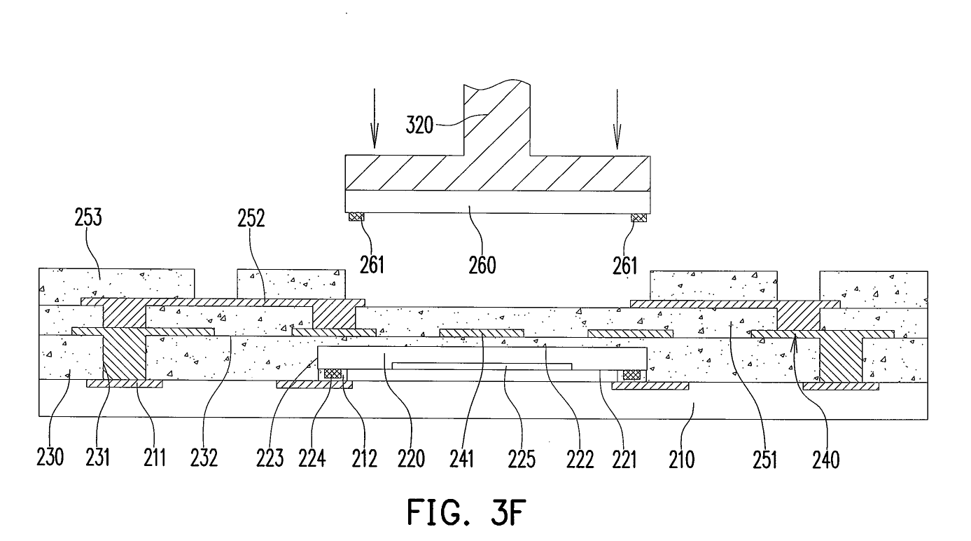

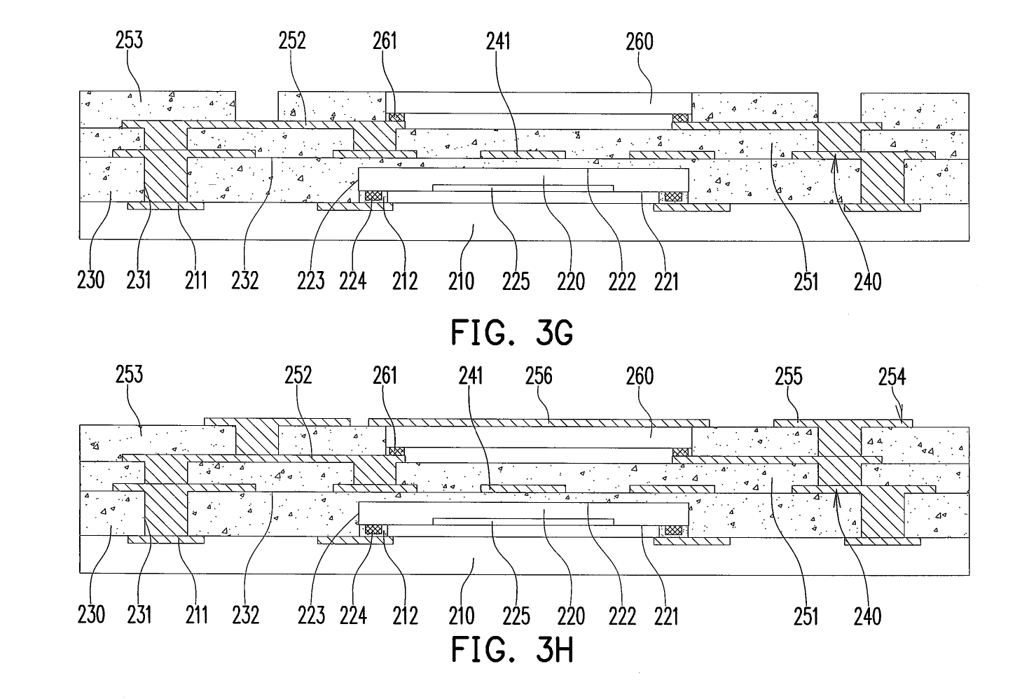

The method of fabricating the build-up package 200 of the optoelectronic chip is as shown in FIGS. 3A to 3H. First, referring to FIG. 3A, a transparent circuit carrier board 210 is provided, and the substrate wiring layer 211 is formed on an upper surface of the transparent circuit carrier board 210. Then, referring to FIG. 3B, the optoelectronic chip 220 is flip-chip bonded to the transparent circuit carrier board 210, and then is electrically connected to the substrate wiring layer 211 via the bumps 224. In this embodiment, the flip-chip bonding method is the antisotropic conducting connection. During the flip-flop bonding, a pick-up apparatus 310 moves, aligns and downwardly presses the optoelectronic chip 220. A bonding material 212 is coated on the transparent circuit carrier board 210, and the bonding material 212 is an antisotropic conductive film (ACF) or an antisotropic conductive paste (ACP). Under a relatively low compressing temperature and paste curing temperature, the bonding material 212 is cured and bonded to the optoelectronic chip 220. The conductive particles of the bonding material 212 are used to achieve the electrically connection between the bumps 224 and the substrate wiring layer 211. The compressing temperature and the paste curing temperature may be controlled within 200° C. to avoid damaging the internal components of the optoelectronic chip 220.

Next, referring to FIG. 3C, a digital inkjet printing or a stencil printing method is used to form the first dielectric layer 230 on the transparent circuit carrier board 210, wherein the first dielectric layer 230 covers the side surfaces 223 and the back surface 222 of the optoelectronic chip 220, and the through holes 231 of the first electric layer 230 penetrate to the substrate wiring layer 211 of the transparent circuit carrier board 210. The first dielectric layer 230 is formed preferably by means of the digital inkjet printing, such that the first dielectric layer 230 achieve various pattern variations and the thickness difference of the first dielectric layer 230 at different regions can be controlled. For example, the thickness of the first dielectric layer 230 on the optoelectronic chip 220 can be relatively thin, the thickness of the first dielectric layer 230 on the transparent circuit carrier board 210 can be relatively thick, and the substrate wiring layer 211 can be exposed at suitable positions.

Next, referring to FIG. 3D, the electroplating method is used to form a first wiring layer 240 on the first dielectric layer 230. The first wiring layer 240 is electrically connected to the substrate wiring layer 211 via the through holes 231 and a part of the wirings 241 of the first wiring layer 240 can extend to above the back surface 222 of the optoelectronic chip 220.

In another embodiment, the solder mask layer 270 shown in FIG. 2 may be formed on the first wiring layer 240 and the first dielectric layer 230 to cover and protect the wirings of the first wiring layer 240. The first wiring layer 240 also may have a plurality of connection pads and a heat sink portion such as the connection pads 255 and the heat sink portion 256 in FIG. 2, and the solder mask layer 270 exposes the connection pads and the heat sink portion, so that the connection pads and the heat sink portion have an exposed surface. Moreover, an electroplated layer 280 shown in FIG. 2 may be formed on the exposed surface of the connection pads and the heat sink portion of the first wiring layer 240.

As shown in FIG. 3E, the second dielectric layer 251 is formed on the first wiring layer 240 sequentially. Then, the second wiring layer 252 is formed on the second dielectric layer 251. Next, as shown in FIG. 3F, after the third dielectric layer 253 is formed on the second wiring layer 252, a thermocompression jig 320 is used to provide the bonding pressure and temperature for the IC chip 260, such that the IC chip 260 is flip-chip bonded to the second wiring layer 252. Then, referring to FIG. 3G, the third dielectric layer 253 is preferably formed on the second wiring layer 252, and the IC chip 260 is embedded in the third dielectric layer 253. Then, referring to FIG. 3H, the third wiring layer 254 is formed on the third dielectric layer 253, and the third wiring layer 254 has a plurality of connection pads 255 and the heat sink portion 256 adhered onto the IC chip 260. Finally, the solder mask layer 270 is formed on the third wiring layer 254 and the third dielectric layer 253, and the solder mask layer 270 exposes the connection pads 255 and the heat sink portion 256, such that the connection pads 255 and the heat sink portion 256 have an exposed surface. The electroplated layer 280 is formed on the exposed surface of the connection pads 255 and the heat sink portion 256, such that the build-up package 200 of the optoelectronic chip as shown in FIG. 2 is formed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A build-up package of an optoelectronic chip, comprising:
a transparent circuit carrier board, having a substrate wiring layer;
at least one optoelectronic chip, flip-chip bonded to the transparent circuit carrier board and electrically connected to the substrate wiring layer;
a first dielectric layer, formed on the transparent circuit carrier board and covering the optoelectronic chip, the first dielectric layer having a plurality of through holes penetrating to the substrate wiring layer of the transparent circuit carrier board; and
a first wiring layer, formed on the first dielectric layer and being electrically connected to the substrate wiring layer via the through holes.

2. The build-up package of the optoelectronic chip as claimed in claim 1, wherein the first dielectric layer is thicker than the optoelectronic chip, and covers a back surface and a plurality of side surfaces of the optoelectronic chip.

3. The build-up package of the optoelectronic chip as claimed in claim 2, wherein the first wiring layer has a plurality of wirings extending to above the optoelectronic chip.

4. The build-up package of the optoelectronic chip as claimed in claim 1, further comprising at least one second dielectric layer and at least one second wiring layer, wherein the second dielectric layer is formed on the first wiring layer, and the second wiring layer is formed on the second dielectric layer.

5. The build-up package of the optoelectronic chip as claimed in claim 4, further comprising at least one IC chip disposed on the second wiring layer.

6. The build-up package of the optoelectronic chip as claimed in claim 4, further comprising at least one third dielectric layer formed on the second wiring layer.

7. The build-up package of the optoelectronic chip as claimed in claim 5, further comprising at least one third dielectric layer formed on the second wiring layer.

8. The build-up package of the optoelectronic chip as claimed in claim 6, wherein the third dielectric layer covers a plurality of side surfaces of the IC chip.

9. The build-up package of the optoelectronic chip as claimed in claim 6, further comprising a third wiring layer formed on the third dielectric layer.

10. The build-up package of the optoelectronic chip as claimed in claim 9, further comprising a solder mask layer formed on the third wiring layer and the third dielectric layer.

11. The build-up package of the optoelectronic chip as claimed in claim 10, wherein the third wiring layer has a plurality of connection pads and a heat sink portion, and the solder mask layer exposes the connection pads and the heat sink portion, so that the connection pads and the heat sink portion have an exposed surface.

12. The build-up package of the optoelectronic chip as claimed in claim 11, further comprising an electroplated layer formed on the exposed surface of the connection pads and the heat sink portion.

13. The build-up package of the optoelectronic chip as claimed in claim 1, further comprising a solder mask layer formed on the first wiring layer and the first dielectric layer.

14. The build-up package of the optoelectronic chip as claimed in claim 13, wherein the first wiring layer has a plurality of connection pads and a heat sink portion, and the solder mask layer exposes the connection pads and the heat sink portion, so that the connection pads and the heat sink portion have an exposed surface.

15. The build-up package of the optoelectronic chip as claimed in claim 14, further comprising an electroplated layer formed on the exposed surface of the connection pads and the heat sink portion.
